(19) United States
(12) Patent Application Publication
(10) Pub. No.: US 2018/0274083 A1
(43) Pub. Date: Sep. 27, 2018

(54) CENTRIFUGAL EVAPORATION SOURCES

(71) Applicant: University of Delaware, Newark, DE (US)

(72) Inventor: Gregory Hanket, Newark, DE (US)

(21) Appl. No.: 15/928,871

(22) Filed: Mar. 22, 2018

Related U.S. Application Data
(60) Provisional application No. 62/475,000, filed on Mar. 22, 2017.

(51) Int. Cl. C23C 14/24; B01D 45/16; C23C 14/14

(52) U.S. Cl. CPC C23C 14/243; C23C 14/14; B01D 45/16

(57) ABSTRACT

Provided herein are centrifugal evaporation sources. These sources include a manifold body, a crucible, an expansion chamber, a centrifugal separator chamber, and an effusion nozzle.

### CROSS REFERENCE TO RELATED APPLICATIONS

This application claims priority to U.S. Provisional Patent Application No. 62/475,000, filed Mar. 22, 2017, the entire contents of which are incorporated herein by reference.

### JOINT RESEARCH AGREEMENT

Pursuant to 35 U.S.C. § 102(c)(1-3), the subject-matter disclosed herein was developed and the claimed invention was made by, or on behalf of, one or more parties to a joint research agreement that was in effect on or before the effective filing date of the claimed invention. The joint research agreement is between JLN Solar, Inc., with offices at Mill Valley, Calif. 94941, and the University of Delaware, with offices at Newark, Del. 19716, an educational nonprofit institution chartered under the laws of the State of Delaware. The claimed invention was made as a result of activities undertaken within the scope of the joint research agreement, and the application for patent for the claimed invention discloses the names of the parties to the joint research agreement.

### BACKGROUND

Vacuum evaporation is widely used for depositing thin films. In this process, an evaporating material (“evaporant”) is held in a vessel and heated to the point that its vapor pressure generates a flowing vapor stream that can be directed toward a substrate, resulting in film growth at some desired rate. This process is conducted in a vacuum chamber, such that gas- or vapor-phase collisions are minimized en route from the evaporation vessel to the substrate and the transfer of mass from the evaporation vessel to the substrate is substantially line-of-sight.

A frequent problem encountered in vacuum evaporation is the generation of droplets within the evaporation source and their ejection onto the substrate. There are at least three conceivable mechanisms by which this could occur. First, given that the vapor pressure of the evaporant is non-zero, and that the evaporation source is operating in a vacuum, the condition for boiling, and accompanying droplet generation, of the evaporant is met. The generation of particles from a sublimating ingot or powder might also occur. Second, if the source exhibits sufficiently large temperature non-uniformities, it is conceivable that some surfaces within the source could drop below the dew point of the vapor, resulting in droplet condensation on these surfaces. Finally, in the case of sources with flow restrictions, the expanding vapor cools, resulting in the formation of small condensate clusters in the flow. There may be other mechanisms by which condensed droplets could be generated. Solid particles might also be generated by similar mechanisms. The source operating conditions typically encountered at manufacturing scales are capable of generating sufficient droplet drag to propel droplets from the source toward the substrate.

Given the number of ways that condensed droplets or particles can be generated, in addition to making all efforts to prevent droplet formation in the first place, a robust source design should be redundant in also incorporating schemes to remove droplets from the vapor stream.

### SUMMARY

Provided herein are vacuum evaporation sources incorporating a static centrifugal separator, and vacuum evaporation sources incorporating a static centrifugal separator and at least one heating element. Also provided herein is a centrifugal evaporation source comprising:
a manifold body;
a crucible configured to contain a volume of evaporant and including a circular cross-section, a bottom, a top rim, and a side wall extension that extends above the top rim to a ceiling of the manifold body to form an annulus with inside walls of the manifold body and to form at least three restriction orifices;
an expansion chamber that is flowably connected to vapor space above the evaporant via the at least three restriction orifices; and
a centrifugal separator chamber that is flowably connected above the evaporant and below the expansion chamber, and circumnavigates the interior of the crucible, wherein the centrifugal separator chamber comprises a first and a second end, the first end of the centrifugal separator chamber is flowably connected to the expansion chamber, and the second end of the centrifugal separator chamber is flowably connected to one or more effusion nozzles.

### BRIEF DESCRIPTION OF THE FIGURES

FIG. 1 depicts an embodiment of a conceptual design for a inward spiral centrifugal separator 100. Vapor 104 enters through hole 102 in the top of ceiling plate 107 (not shown), revolves around a circular path, then flows radially inward and down through hole 103 in floor plate 105.

FIG. 2 depicts a speed profile of Cu vapor flowing clockwise through centrifugal separator 100 of FIG. 1. The flow cross-section for gravimetric flow calculation is denoted by the dashed line.

FIG. 3 depicts a pressure profile of Cu vapor flowing clockwise through centrifugal separator 100 of FIG. 1.

FIG. 4 depicts a density profile of Cu vapor flowing clockwise through centrifugal separator 100 of FIG. 1. The flow cross-section for gravimetric flow calculation is denoted by the dashed line.

FIG. 5 depicts a temperature profile of Cu vapor flowing clockwise through centrifugal separator 100 of FIG. 1.

FIG. 6 is a graphical depiction of vapor flow speed across the flow cross-section denoted in FIG. 2. The averaged flow speed is 45.6 m/sec.

FIG. 7 is a graphical depiction of gravimetric vapor density across the flow cross-section denoted in FIG. 4. The averaged vapor density is 5.93×10⁻⁵ kg/m³.

FIG. 8 depicts predicted trajectories of droplets of varying diameter around centrifugal separator 100. Droplets with diameter <0.0022 micron (2.2 nm) escape centrifugal separator 100, while larger ones impact exterior wall 101 and are removed from vapor stream 104.

FIG. 9 depicts an embodiment of a vacuum evaporation source, vacuum evaporation source 200, comprising a centrifugal separator configuration utilizing a 3-dimensional helical configuration, helical centrifugal separator 210. In this implementation, centrifugal separator 210 is located above evaporant 201 (e.g., Cu melt) to remove spits generated by boiling evaporant 201 (e.g., Cu liquid). After spit removal, vapor 214 (e.g., Cu vapor) flows out to expansion chamber 203 enclosed within manifold body 206, down to effusion nozzle 202, and out towards a substrate (not shown).

FIG. 10 depicts an embodiment of a position of centrifugal separator 310 in downward-evaporating, single-nozzle (302) source 300.

FIG. 11 depicts an embodiment of locations of centrifugal separators 410 in a downward-evaporating, multiple-nozzle (402) source 400.

FIG. 12 depicts an embodiment of a position of centrifugal separator 510 in an upward-evaporating, single-nozzle (502) source 500.

FIG. 13 depicts an embodiment of locations of centrifugal separators 610 in an upward-evaporating, multiple-nozzle (602) source 600.

FIG. 14 depicts an embodiment of a position of centrifugal separator 710 in a sideways-evaporating, single-nozzle (702) source 700.

FIG. 15 depicts an embodiment of positions of centrifugal separators 810 in a sideways-evaporating, multiple-nozzle (802) source 800.

FIG. 16 depicts a schematic of an embodiment of downward-evaporating effusion source 900.

FIG. 17 depicts a 10 μm Cu film deposited at an evaporation rate F=13.4 g/hr, showing spits of about 5 μm diameter at a density of 10 spits/mm².

FIG. 18 depicts an effect of a lid heater on expansion chamber 1003 temperature in source 1000. Lid 1007 is not heated in left panel; source body 1008 is heated (2540 W) and effusion nozzle 1002 is heated (1370 W). Lid 1007 is heated (900 W) in right panel; source body 1008 is heated (1440 W) and effusion nozzle 1002 is heated (1370 W).

FIG. 19 depicts an effect of lid power on evaporant chamber wall temperature profile from floor center point to expansion orifice.

### DETAILED DESCRIPTION

Provided herein are centrifugal evaporation sources. These sources include a manifold body, a crucible, an expansion chamber, a centrifugal separator chamber, and an effusion nozzle.

Some techniques for the removal of particulates from a gas stream include centrifugal separation. Generally speaking, a volume of gas and suspended particulate are flowed in a circular trajectory so that the denser particles travel toward the outer edges of the flow. The clean gas is then drawn off near the axis of rotation. A variety of configurations have been developed—some static (i.e. no moving parts), some with impellers to induce the rotation.

Provided herein are vacuum evaporation sources incorporating a static centrifugal separator. The centrifugal separator incorporates a flow channel or channels that direct the flowing vapor to follow a circular trajectory in excess of 180°, i.e. in excess of % of a revolution. Two configurations are described, though these are not intended to be limiting. The first is 2-dimensional flow trajectory that directs the flow in an inward spiral configuration. The second configuration is a 3-D helical flow path. The choice of either configuration, or both, and the design, i.e. the number of revolutions in either configuration, is determined by considering the desired separation performance—a longer flow path removes smaller droplets—against the volume in the evaporation source available for incorporation of the separator as well as the tolerable pressure drop within the separator—as the flow path within the separator is lengthened, a greater pressure drop occurs resulting in an overall reduction in flow from the evaporation source. In some embodiments, the separator can immediately precede the effusion nozzle that directs the vapor toward the substrate, to prevent the possible entrainment of droplets within the source after the vapor has already flowed through the centrifugal separator. A number of configurations are possible incorporating the permutations of a single- or multiple-effusion nozzle sources (with a centrifugal separator at each nozzle), upward-, downward-, or sideways-effusing sources, and spiral or helical centrifugal separators.

Vapor flow pressure and vapor flow velocity are generally required when predicting performance of a centrifugal separator. This can then be used in the formula of Epstein for predicting the drag on a suspended droplet. This drag can then be used in predicting the trajectory of the droplet both in terms of outward inertia and downward gravitational force.

Evaporation sources for manufacturing applications typically operate in the “transitional” flow regime, which is neither viscous nor free molecular. Mathematical expressions for transitional flow exist for only a limited number of flow geometries, i.e. tubes. Thus, modeling of the flow through the centrifugal separator is best accomplished using the Direct Monte Carlo Simulation (DSMC) method, although modeling the flow through the centrifugal separator as a straightened tube with identical flow cross section could also yield useful results.

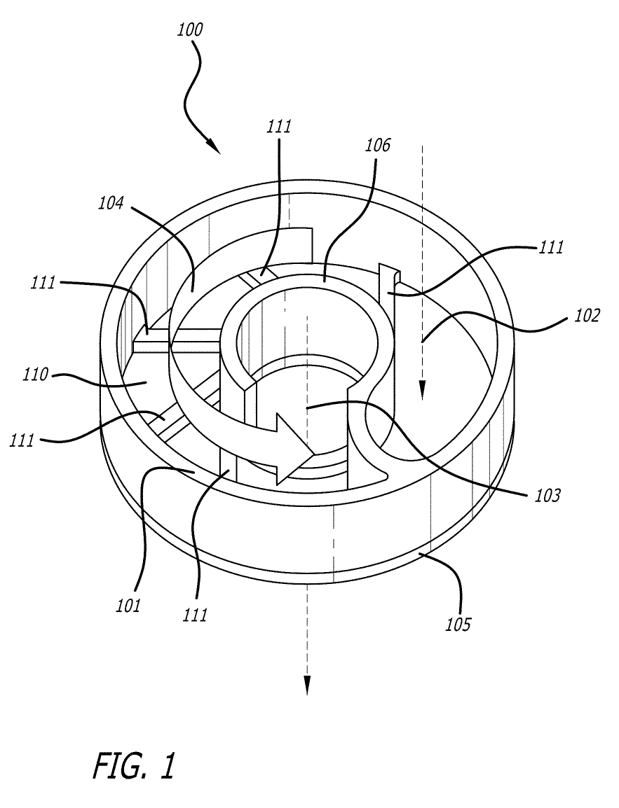

One embodiment of a centrifugal separator is shown in FIG. 1. The vapor enters through a hole in the top plate (not shown), revolves around the separator, then flows radially inward and down through the separator exit. A series of ribs (111) on the floor (110) of the separator traps droplets from being dragged across for floor to the separator exit. In some embodiments, the separator includes a series of ribs (e.g., 2, 3, 4, 5, 6, 7, 8, 9, or 10 ribs) on the floor of the separator. In some embodiments, the vapor flow path of the separator is in excess of 180°. In some embodiments, the separator includes a series of ribs (e.g., 2, 3, 4, 5, 6, 7, 8, 9, or 10 ribs) on the floor of the separator, and the vapor flow path of the separator is in excess of 180°.

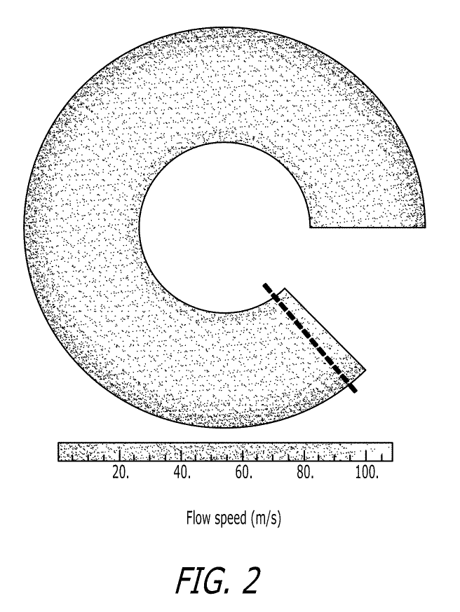

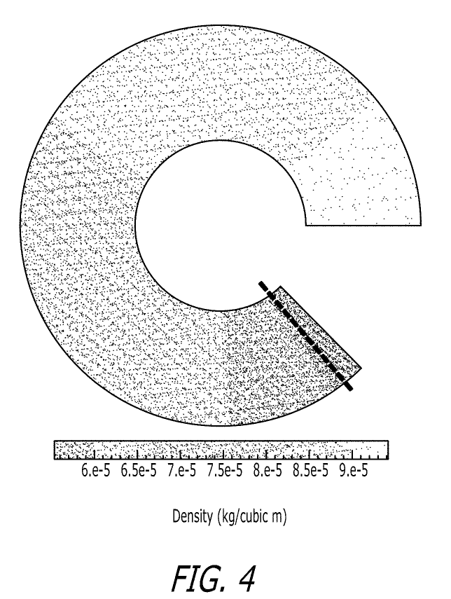

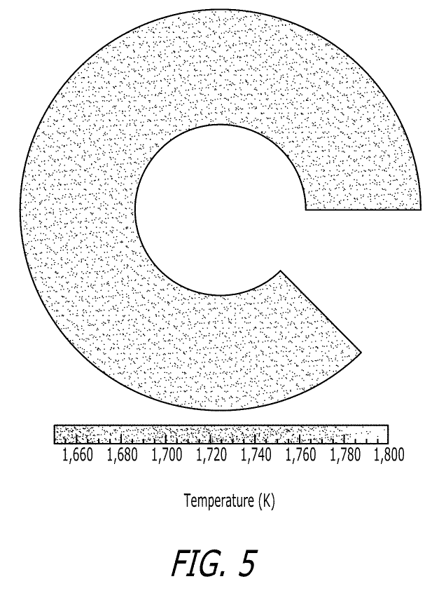

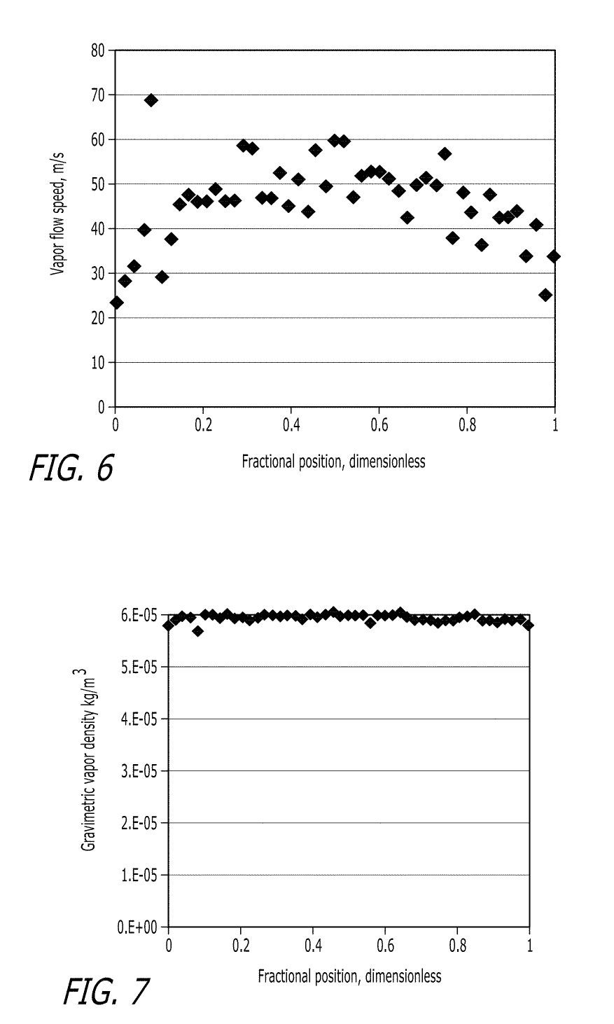

Results of a simplified 2-D DSMC model of the separator are depicted in FIGS. 2-5 for Cu vapor at 1450° C. (1723K) flowing through the centrifugal separator of FIG. 1. The outer and inner diameters are 6.7 and 2.9 cm, respectively. The vapor entry is approximated by a straight-line constant pressure surface at about 20.5 Pa, and the vapor exit is approximated by a straight-line constant pressure surface at 13.5 Pa. Speed, pressure, gravimetric vapor density, and temperature are shown. The gravimetric flow rate is approximated by multiplying the averaged gravimetric density and speed across the vapor exit as depicted in FIG. 6 and FIG. 7. The scatter in the model data are due to the stochastic nature of the DSMC method. The average flux is 0.0027 kg/m²/s, or 0.00027 g/cm²/s. For the depicted centrifugal separator with a channel width of 3.8 cm and channel height of 2.9 cm, the flow rate is 10.7 g/hr.

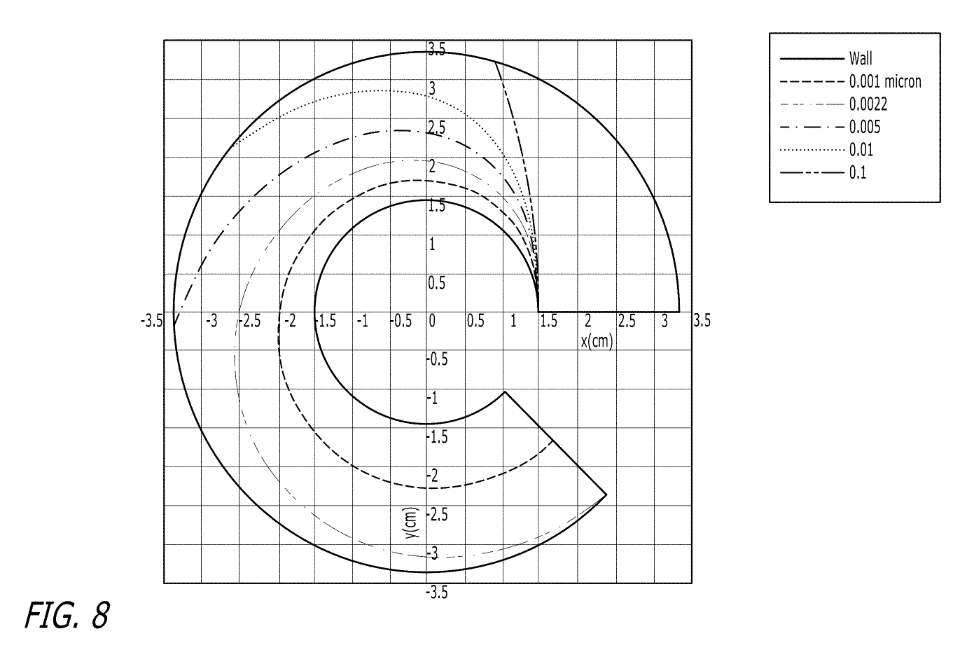

Given averaged values for speed and pressure generated by the DSMC method, the trajectories of various droplets can be calculated using the drag formula of Epstein. A simplified flow description using position-independent, constant speed of 45.6 m/s and constant pressure of 17 Pa is used. The drag on a droplet is approximated using the “Diffuse reflection with accommodation—perfect thermal conductor” (Case 4b) model of Epstein, though the “Uniform evaporation” (Case 1) condition could also be applicable. In either event, these quantitative drag predictions only deviate from their averaged value by ±16%. The predicted droplet trajectories around the separator are shown in FIG. 8. In some embodiments, the centrifugal separator can remove all droplets greater than about 0.0022 micron (2.2 nm) (e.g., 0.0022 micron±16%, 0.0022-0.003 micron, 0.003-0.004 micron, 0.004-0.005 micron) in diameter.

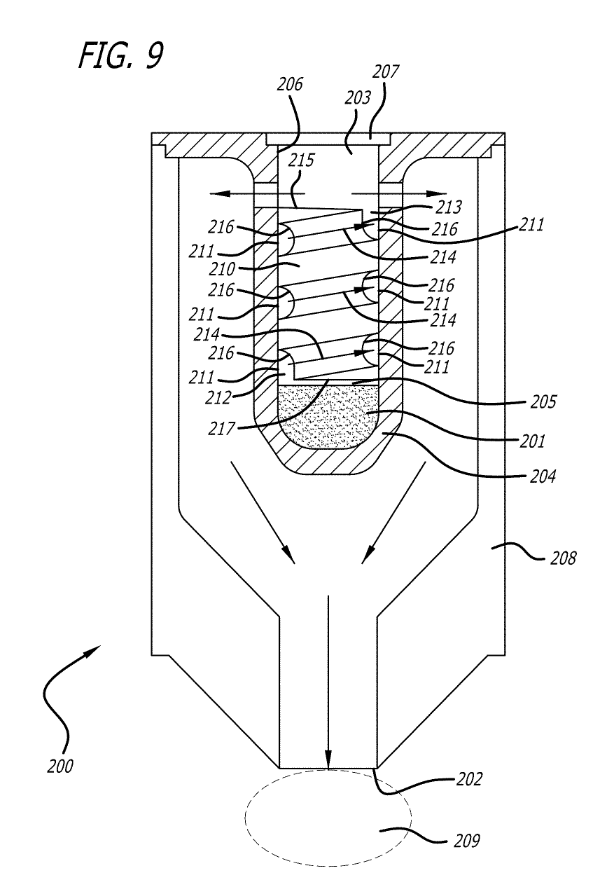

In the second embodiment, a helical centrifugal separator (210) is shown in FIG. 9. In some embodiments, it is advantageous over the 2-D spiral design because the flow path can be lengthened without a loss in flow cross section. The fabrication can also be simpler with a 2D spiral design. A cylinder with a spiral-cut outer trench can simply be inserted into a cylindrical shell to form a helical flow path.

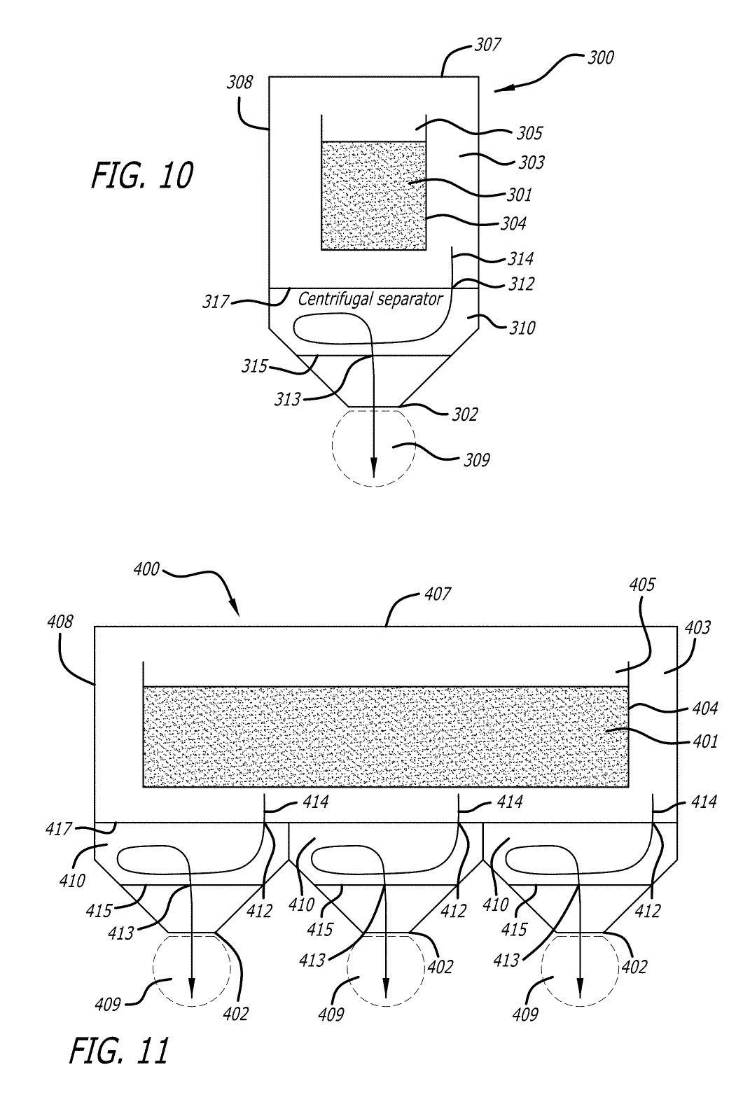

The incorporation of centrifugal separators into various sources is shown in FIGS. 10-15. In one embodiment, as illustrated in FIG. 10, a spiral centrifugal separator 310 is situated atop effusion nozzle 302 in downward-evaporating source 300. In some embodiments, the spiral centrifugal separators or centrifugal separators provided herein are helical centrifugal separators.

When considering incorporation into a sideways-evaporating nozzle, it is noted that the acceleration due to drag is orders of magnitude higher than drag due to gravitational acceleration. Thus, the performance of the centrifugal separator may not be affected by orientation. However, in some embodiments the centrifugal separator can be oriented such that the vapor flows upward into the separator exit orifice. This upward flow prevents droplets from falling down off of the outer wall and into the exit orifice.

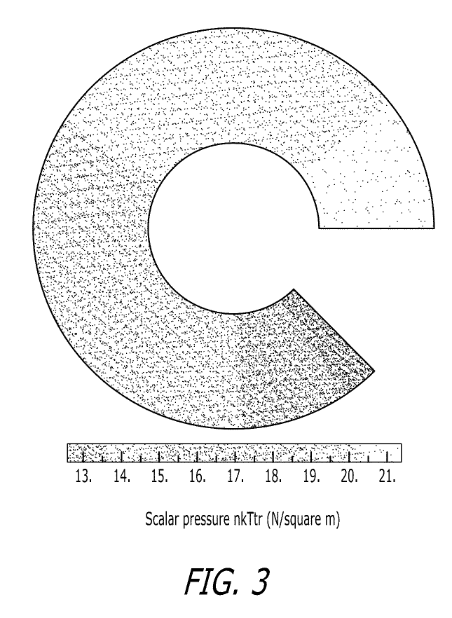

Given that effusion rate scales proportionally with pressure in the free-molecular flow regime and as pressure-squared in the transistional regime, the separator induces an effusion rate decrease between 38 and 62%. Considering FIG. 3 as an example, the pressure drops from 21 Pa to 13 Pa as the vapor flows through the separator.

The devices provided herein can be used with low vapor pressure evaporants, e.g. Ag, Cu, In, and Ga, for the evaporative deposition of Cu(InGa)Se₂ or (AgCu)(InGa)Se₂ thin films for photovoltaic applications, In and Sn for the evaporative deposition of indium-tin-oxide transparent conductive films, or Al, Ga, and In for III-V film deposition. However, as vacuum evaporation necessarily satisfies the condition for boiling, i.e. the saturation pressure of the evaporant exceeds the surrounding ambient pressure, the centrifugal separator is generally relevant to film deposition by vacuum evaporation, which includes vacuum deposition of organic light-emitting-diode (OLED) displays. Sublimation of powdered or solid materials can result in particles outside of a specified size range entrained in the flowing vapor. Centrifugal separation can be used to restrict particles in a flowing vapor to a specified size range when the vapor derives from sublimation of powdered or solid materials. Sublimated materials can include, but are not limited to, lead halide PbX₂ (wherein X is halogen, e.g., F, Cl, Br, or I) compounds and methyl ammonium halide CH₃NH₃X compounds (wherein X is halogen, e.g., F, Cl, Br, or I) used in the deposition of perovskite thin films, and II-VI compounds (Zn,Cd,Hg)(S,Se,Te). The devices described herein may also be used for preparing evaporated optical coatings where surface defects (e.g. due to source spitting) are minimized.

In some embodiments, the vacuum evaporation sources comprise a lid. In some embodiments, the vacuum evaporation sources comprise a lid heating element. In some embodiments, the lid heating element refines control of the source temperature profile to prevent vapor saturation and subsequent condensation and spitting.

In some embodiments, the vacuum evaporation sources comprise a centrifugal separator. In some embodiments, the centrifugal separator is a helical centrifugal separator.

In some embodiments the centrifugal separator removes all or substantially all droplets greater than about 0.001 micron in diameter (e.g., greater than about 0.0022 micron, e.g., greater than about 0.003 micron, e.g., greater than about 0.004 micron, e.g., greater than about 0.005 micron, e.g., greater than about 0.01 micron, e.g., greater than about 0.1 micron). In some embodiments, removing substantially all droplets means removing greater than about 80%, greater than about 90%, greater than about 95%, greater than about 96%, greater than about 97%, greater than about 98%, or greater than about 99% of a particular size particle(s).

In some embodiments, the vacuum evaporation sources comprise an internal pressure of about 5 Pa to about 100 Pa (e.g., about 5 Pa to about 50 Pa, about 5 Pa to about 25 Pa, about 10 Pa to about 25 Pa, about 10 Pa to about 20 Pa, about 13 Pa to about 21 Pa, about 17 Pa). In some embodiments, the internal pressure drops from about 25 Pa to about 10 Pa as the vapor flows through the separator toward the effusion nozzle. In some embodiments, the internal pressure drops from about 21 Pa to about 13 Pa as the vapor flows through the separator toward the effusion nozzle. In some embodiments, the internal pressure drops from about 20 Pa to about 10 Pa as the vapor flows through the separator toward the effusion nozzle.

In some embodiments, the vacuum evaporation sources allow for spit-free Cu evaporation rates of 15 to 30 g/hr (e.g., 15 to 20 g/hr, 20 to 25 g/hr, 25 to 30 g/hr, 15 to 25 g/hr, 20 to 30 g/hr, 15 g/hr, 20 g/hr, 25 g/hr, or 30 g/hr).

In some embodiments, the vacuum evaporation sources allow for spit-free In evaporation rates of 15 to 30 g/hr (e.g., 15 to 20 g/hr, 20 to 25 g/hr, 25 to 30 g/hr, 15 to 25 g/hr, 20 to 30 g/hr, 15 g/hr, 20 g/hr, 25 g/hr, or 30 g/hr).

In some embodiments, the vacuum evaporation sources allow for spit-free Ga evaporation rates of 15 to 30 g/hr (e.g., 15 to 20 g/hr, 20 to 25 g/hr, 25 to 30 g/hr, 15 to 25 g/hr, 20 to 30 g/hr, 15 g/hr, 20 g/hr, 25 g/hr, or 30 g/hr).

In some embodiments, the vacuum evaporation sources allow for spit-free Se evaporation rates of 15 to 30 g/hr (e.g., 15 to 20 g/hr, 20 to 25 g/hr, 25 to 30 g/hr, 15 to 25 g/hr, 20 to 30 g/hr, 15 g/hr, 20 g/hr, 25 g/hr, or 30 g/hr).

In some embodiments, the vacuum evaporation sources allow for spit-free CuInGaSe evaporation rates of 15 to 30 g/hr (e.g., 15 to 20 g/hr, 20 to 25 g/hr, 25 to 30 g/hr, 15 to 25 g/hr, 20 to 30 g/hr, 15 g/hr, 20 g/hr, 25 g/hr, or 30 g/hr).

In some embodiments, the vacuum evaporation sources allow for spit-free CuAgInGaSe evaporation rates of 15 to 30 g/hr (e.g., 15 to 20 g/hr, 20 to 25 g/hr, 25 to 30 g/hr, 15 to 25 g/hr, 20 to 30 g/hr, 15 g/hr, 20 g/hr, 25 g/hr, or 30 g/hr).

In some embodiments, the vacuum evaporation sources comprise a manifold body. In some embodiments, the manifold body comprises a heater.

In some embodiments, the vacuum evaporation sources comprise an effusion nozzle. In some embodiments, the effusion nozzle comprises a heater.

In some embodiments, the vacuum evaporation sources comprise a ceiling. In some embodiments, the ceiling comprises a heater.

### Evaporation Sources

In some embodiments, provided herein are a centrifugal evaporation sources comprising: a manifold body; a crucible configured to contain a volume of evaporant; an expansion chamber; and a centrifugal separator.

In some embodiments, a centrifugal separator chamber can be flowably connected above the evaporant and below the expansion chamber.

In some embodiments, a centrifugal separator chamber can circumnavigate the interior of the crucible. In other embodiments, the centrifugal separator chamber can circumnavigate another portion of an evaporation source.

In some embodiments, the centrifugal separator chamber comprises a first and a second end, wherein the first end of the centrifugal separator chamber is flowably connected to the crucible and the second end of the centrifugal separator chamber is flowably connected to one or more effusion nozzles. In other embodiments, the first end of the centrifugal separator chamber is flowably connected to the expansion chamber.

In one aspect, provided herein is a centrifugal evaporation source comprising:
a manifold body;
a crucible configured to contain a volume of evaporant and including a circular cross-section, a bottom, a top rim, and a side wall extension that extends above the top rim to a ceiling of the manifold body to form an annulus with inside walls of the manifold body and to form at least three restriction orifices;
an expansion chamber that is flowably connected to vapor space above the evaporant via the at least three restriction orifices; and
a centrifugal separator chamber that is flowably connected above the evaporant and below the expansion chamber, and circumnavigates the interior of the crucible, wherein the centrifugal separator chamber comprises a first and a second end, the first end of the centrifugal separator chamber is flowably connected to the expansion chamber, and the second end of the centrifugal separator chamber is flowably connected to one or more effusion nozzles.

In some embodiments, at least one wall of the centrifugal separator chamber comprises a heating element capable of heating the at least one wall of the centrifugal separator chamber to a temperature of between 300° C. and 1,600° C. In some embodiments, the temperature is between 300° C. and 1,000° C. In some embodiments, the temperature is between 300° C. and 700° C. In some embodiments, the temperature is between 300° C. and 600° C. In some embodiments, the temperature is between 300° C. and 500° C. In some embodiments, the temperature is between 400° C. and 500° C.

In some embodiments, the one or more effusion nozzles comprise a heating element capable of heating the one or more effusion nozzles independently to a temperature of between 300° C. and 1,600° C. In some embodiments, the temperature is between 300° C. and 1,000° C. In some embodiments, the temperature is between 300° C. and 700° C. In some embodiments, the temperature is between 300° C. and 600° C. In some embodiments, the temperature is between 300° C. and 500° C. In some embodiments, the temperature is between 400° C. and 500° C.

In some embodiments, the manifold body comprises a heating element capable of heating the manifold body to a temperature of between 300° C. and 1,600° C. In some embodiments, the temperature is between 300° C. and 1,000° C. In some embodiments, the temperature is between 300° C. and 700° C. In some embodiments, the temperature is between 300° C. and 600° C. In some embodiments, the temperature is between 300° C. and 500° C. In some embodiments, the temperature is between 400° C. and 500° C.

In some embodiments, the ceiling of the manifold body comprises a heating element capable of heating the ceiling of the manifold body to a temperature of between 300° C. and 1,600° C. In some embodiments, the temperature is between 300° C. and 1,000° C. In some embodiments, the temperature is between 300° C. and 700° C. In some embodiments, the temperature is between 300° C. and 600° C. In some embodiments, the temperature is between 300° C. and 500° C. In some embodiments, the temperature is between 400° C. and 500° C.

In some embodiments, the centrifugal separator chamber is an N-helical centrifugal separator chamber, wherein N is mono, di, tri, quadra, penta, hexa, hepta, octa, nona, or deca, and each helix independently has a first end flowably connected to the expansion chamber and a second end flowably connected to the one or more effusion nozzles. In some embodiments, N is mono, di or tri. In some embodiments, the centrifugal separator chamber is a mono-helical centrifugal separator chamber. In some embodiments, the centrifugal separator chamber is a di-helical centrifugal separator chamber. In some embodiments, the centrifugal separator chamber is a tri-helical centrifugal separator chamber.

In some embodiments, the one or more effusion nozzles are oriented to direct a vapor flow out of the thermal evaporation source vertically downward, in one or more horizontal directions, or in one or more directions intermediate between horizontal and vertically downward.

In some embodiments, the crucible is a crucible formed of boron nitride. In some embodiments, the crucible is a crucible formed of graphite. In some embodiments, the crucible is a crucible formed of boron nitride and graphite.

In some embodiments, the evaporation source includes an effusion nozzle configured to produce a vertically downward vapor flow.

In some embodiments, the at least three restriction orifices comprises eight orifices evenly spaced around a circumference of the crucible.

In some embodiments, the evaporation sources further comprise a lid attached to the crucible, wherein the lid includes one or more additional restriction orifices.

In some embodiments, the lid provides an added expansion space.

In some embodiments, the lid comprises a heating element capable of heating the lid to a temperature of between 300° C. and 1,600° C. In some embodiments, the temperature is between 300° C. and 1,000° C. In some embodiments, the temperature is between 300° C. and 700° C. In some embodiments, the temperature is between 300° C. and 600° C. In some embodiments, the temperature is between 300° C. and 500° C. In some embodiments, the temperature is between 400° C. and 500° C.

In some embodiments, the manifold body is formed of graphite.

In some embodiments, the first end of the centrifugal separator chamber is flowably connected to the evaporant.

In some embodiments, the second end of the centrifugal separator chamber is flowably connected to the manifold, and the manifold is flowably connected to one or more effusion nozzles.

### Single-Nozzle Helical Centrifugal Sources

FIG. 9 shows a cross-sectional side view of one possible configuration of helical centrifugal source 200. Viewed from the top, the cross-section of source 200 may be circular, square, or rectangular. In some embodiments, source 200 may comprise a threaded lid and body (not shown) for ease of changing evaporant 201.

The device includes a volume of evaporant 201 contained in crucible 204, which also contains vapor space 205 above evaporant 201. Vapor 214 from vapor space 205 enters helical centrifugal separator 210 through hole 212 in ceiling plate 217 and exits through hole 213 in floor plate 215 into expansion chamber 203 enclosed within manifold body 206. One function of hole 212 (a restriction orifice), and thereby helical centrifugal separator 210, is to cause evaporant 201 vapor pressure in expansion chamber 203 to be less than the thermodynamic saturation pressure of evaporant 201, thereby inhibiting evaporant 201 condensation within manifold body 206 or in effusion nozzle 202.

A heating element (typically unitary) heats some or all of source 200. There may be a single heating element, or two or more heating elements. In some embodiments, one heating element primarily heats manifold body 206, or lid 207, while multiple heating elements heat crucible 204 containing evaporant 201. In some embodiments, one heating element primarily heats crucible 204 and evaporant 201, while multiple elements heat manifold body 206. In some embodiments, one heating element primarily heats lid 207, one heating element primarily heats crucible 204 and evaporant 201, and multiple elements heat manifold body 206. In some embodiments, multiple heating elements heat source body 208. In some embodiments, one or multiple heating elements heat effusion nozzle 202. In some embodiments, a heating element may be either spiral-wound around the perimeter of source 200 (source body 208), or serpentine with the straight runs of the heating element oriented vertically. Alternatively, a number of single straight heating elements, oriented vertically, may be disposed around source body 208. In some embodiments, the heating element material is graphite. In some embodiments, the heating element material is electrically insulated from source body 208 with a high-temperature electrical insulator such as boron nitride.

Effusion nozzle 202 is situated on one face of source 200. Effusion plume 209 of vapor 214 exits effusion nozzle 202, and is deposited on a substrate.

During operation, some or all of source 200 is maintained at a temperature above the saturation point of vaporized evaporant 201 within source 200 to prevent condensation. An insulating layer typically surrounds substantially the entire source with the exception of effusion nozzle 202 and electrical feed-throughs for the heating elements.

Evaporant 201 may be any element, or compound thereof, that has high vacuum deposition properties in forming a photovoltaic absorber layer. In some embodiments, the element, or compound thereof, comprises silver, copper, indium, gallium and selenium. In use, substrate translation direction during use of source 200 is normal to the plane of the cross-section of source 200 shown in FIG. 9.

In some embodiments, in order to minimize the surface-area-to-volume ratio of source 200, source 200 is cylindrical in geometry; i.e., circular in cross-section when viewed from the top. In some embodiments, crucible 204 has a larger circumference than manifold body 206, as prolonged operating duration may be achieved by increasing the volume of the evaporant 201 chamber. In some embodiments, the circumference of the manifold is limited in order to reduce the thermal loading of source 200, while still maintaining sufficient internal vapor conductance along the interior of the manifold to avoid an excessive vapor pressure drop. These design considerations do not limit source 200 design to cylindrical designs. Other considerations such as the method of heating may also factor into the choice of source 200 geometry, such as a square or rectangular perimeter instead of a circular perimeter. Furthermore, source 200 is not limited to low-aspect-ratio cross sections. High-aspect-ratio cross sections, with large perimeter-to-area ratios, may also be used.

### Downwards-Evaporating Single-Nozzle Centrifugal Sources

FIG. 10 shows a cross-sectional side view of one possible configuration of centrifugal source 300. Viewed from the top, the cross-section of source 300 may be circular, square, or rectangular. In some embodiments, source 300 may comprise a threaded lid and body (not shown) for ease of changing evaporant 301.

The device includes a volume of evaporant 301 contained in crucible 304, which also contains vapor space 305 above evaporant 301. Vapor 314 from vapor space 305 enters expansion chamber 303, then enters centrifugal separator 310 through hole 312 in ceiling plate 317 and exits through hole 313 in floor plate 315 into an effusion head space enclosed by effusion nozzle 302 and exits effusion nozzle 302 as vapor plume 309. One function of hole 312 (a restriction orifice), and thereby centrifugal separator 310, is to cause evaporant 301 vapor pressure in the effusion head space to be less than the thermodynamic saturation pressure of evaporant 301, thereby inhibiting evaporant 301 condensation within the effusion head space.

A heating element (typically unitary) heats some or all of source 300. There may be a single heating element, or two or more heating elements. In some embodiments, one heating element primarily heats source body 308, or lid 307, while multiple heating elements heat crucible 304 containing evaporant 301. In some embodiments, one heating element primarily heats crucible 304 and evaporant 301, while multiple elements heat source body 308. In some embodiments, one heating element primarily heats lid 307, one heating element primarily heats crucible 304 and evaporant 301, and multiple elements heat source body 308. In some embodiments, multiple heating elements heat source body 308. In some embodiments, one or multiple heating elements heat effusion nozzle 302. In some embodiments, a heating element may be either spiral-wound around the perimeter of source 300 (source body 308), or serpentine with the straight runs of the heating element oriented vertically. Alternatively, a number of single straight heating elements, oriented vertically, may be disposed around source body 308. In some embodiments, the heating element material is graphite. In some embodiments, the heating element material is electrically insulated from source body 308 with a high-temperature electrical insulator such as boron nitride.

Effusion nozzle 302 is situated on one face of source 300. Effusion plume 309 of vapor 314 exits effusion nozzle 302, and is deposited on a substrate.

During operation, some or all of source 300 is maintained at a temperature above the saturation point of vaporized evaporant 301 within source 300 to prevent condensation. An insulating layer typically surrounds substantially the entire source with the exception of effusion nozzle 302 and electrical feed-throughs for the heating elements.

Evaporant 301 may be any element, or compound thereof, that has high vacuum deposition properties in forming a photovoltaic absorber layer. In some embodiments, the element, or compound thereof, comprises silver, copper, indium, gallium and selenium. In use, substrate translation direction during use of source 300 is normal to the plane of the cross-section of source 300 shown in FIG. 10.

In some embodiments, in order to minimize the surface-area-to-volume ratio of source 300, source 300 is cylindrical in geometry; i.e., circular in cross-section when viewed from the top. These design considerations do not limit source 300 design to cylindrical designs. Other considerations such as the method of heating may also factor into the choice of source 300 geometry, such as a square or rectangular perimeter instead of a circular perimeter. Furthermore, source 300 is not limited to low-aspect-ratio cross sections. High-aspect-ratio cross sections, with large perimeter-to-area ratios, may also be used.

### Downwards-Evaporating Multiple-Nozzle Centrifugal Sources

FIG. 11 shows a cross-sectional side view of one possible configuration of centrifugal source 400. Viewed from the top, the cross-section of source 400 may be circular, square, or rectangular. In some embodiments, source 400 may comprise a threaded lid and body (not shown) for ease of changing evaporant 401.

The device includes a volume of evaporant 401 contained in crucible 404, which also contains vapor space 405 above evaporant 401. Vapors 414 from vapor space 405 enter expansion chamber 403, then enter centrifugal separators 410 through holes 412 in ceiling plate 417 and exit through holes 413 in floor plate 415 into effusion head spaces enclosed by effusion nozzles 402 and exits effusion nozzles 402 as vapor plumes 409. One function of holes 412 (a restriction orifice), and thereby centrifugal separators 410, is to cause evaporant 401 vapor pressure in the effusion head spaces to be less than the thermodynamic saturation pressure of evaporant 401, thereby inhibiting evaporant 401 condensation within the effusion head spaces.

A heating element (typically unitary) heats some or all of source 400. There may be a single heating element, or two or more heating elements. In some embodiments, one heating element primarily heats source body 408, or lid 407, while multiple heating elements heat crucible 404 containing evaporant 401. In some embodiments, one heating element primarily heats crucible 404 and evaporant 401, while multiple elements heat source body 408. In some embodiments, one heating element primarily heats lid 407, one heating element primarily heats crucible 404 and evaporant 401, and multiple elements heat source body 408. In some embodiments, multiple heating elements heat source body 408. In some embodiments, one or multiple heating elements heat effusion nozzles 402. In some embodiments, a heating element may be either spiral-wound around the perimeter of source 400 (source body 408), or serpentine with the straight runs of the heating element oriented vertically. Alternatively, a number of single straight heating elements, oriented vertically, may be disposed around source body 408. In some embodiments, the heating element material is graphite. In some embodiments, the heating element material is electrically insulated from source body 408 with a high-temperature electrical insulator such as boron nitride.

Effusion nozzles 402 are situated on one face of source 400. Effusion plumes 409 of vapors 414 exit effusion nozzles 402, and are deposited on a substrate.

During operation, some or all of source 400 is maintained at a temperature above the saturation point of vaporized evaporant 401 within source 400 to prevent condensation. An insulating layer typically surrounds substantially the entire source with the exception of effusion nozzle 402 and electrical feed-throughs for the heating elements.

Evaporant 401 may be any element, or compound thereof, that has high vacuum deposition properties in forming a photovoltaic absorber layer. In some embodiments, the element, or compound thereof, comprises silver, copper, indium, gallium and selenium. In use, substrate translation direction during use of source 400 is normal to the plane of the cross-section of source 400 shown in FIG. 11.

In some embodiments, in order to minimize the surface-area-to-volume ratio of source 400, source 400 is cylindrical in geometry; i.e., circular in cross-section when viewed from the top. These design considerations do not limit source 400 design to cylindrical designs. Other considerations such as the method of heating may also factor into the choice of source 400 geometry, such as a square or rectangular perimeter instead of a circular perimeter. Furthermore, source 400 is not limited to low-aspect-ratio cross sections. High-aspect-ratio cross sections, with large perimeter-to-area ratios, may also be used.

### Upwards-Evaporating Single-Nozzle Centrifugal Sources

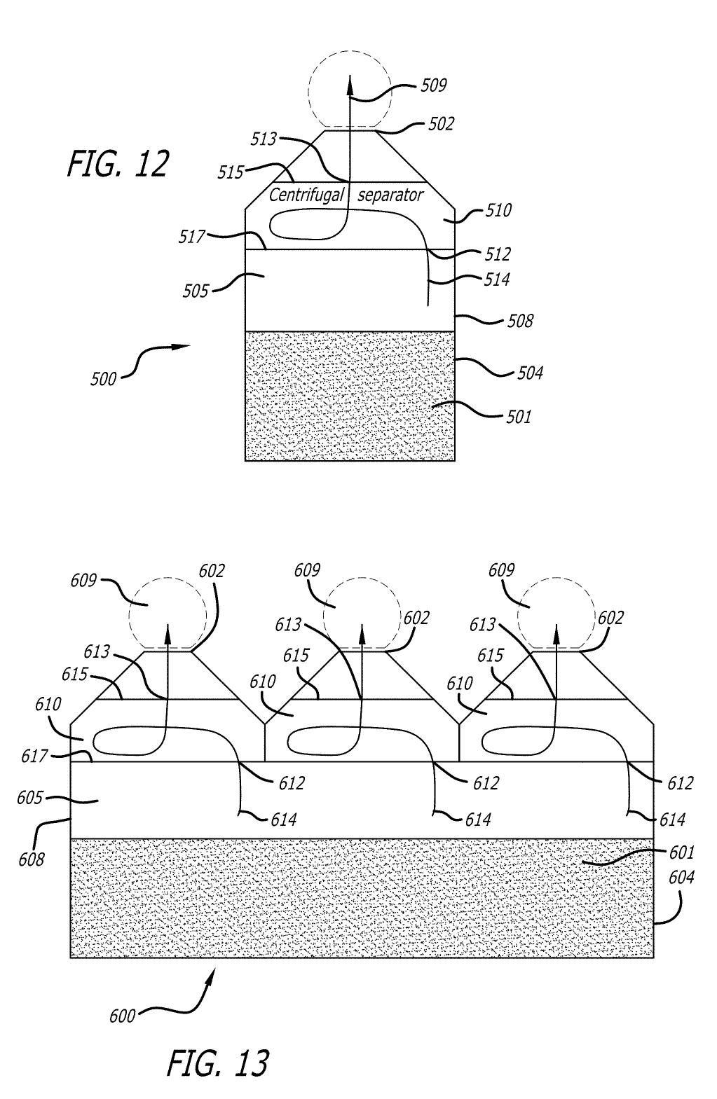

FIG. 12 shows a cross-sectional side view of one possible configuration of centrifugal source 500. Viewed from the bottom, the cross-section of source 500 may be circular, square, or rectangular. In some embodiments, source 500 may comprise a threaded lid and body (not shown) for ease of changing evaporant 501.

The device includes a volume of evaporant 501 contained in crucible 504, which also contains vapor space 505 above evaporant 501. Vapor 514 from vapor space 505 enters centrifugal separator 510 through hole 512 in ceiling plate 517 and exits through hole 513 in floor plate 515 into an effusion head space enclosed by effusion nozzle 502 and exits effusion nozzle 502 as vapor plume 509. One function of hole 512 (a restriction orifice), and thereby centrifugal separator 510, is to cause evaporant 501 vapor pressure in the effusion head space to be less than the thermodynamic saturation pressure of evaporant 501, thereby inhibiting evaporant 501 condensation within the effusion head space.

A heating element (typically unitary) heats some or all of source 500. There may be a single heating element, or two or more heating elements. In some embodiments, one heating element primarily heats source body 508, while multiple heating elements heat crucible 504 containing evaporant 501. In some embodiments, one heating element primarily heats crucible 504 and evaporant 501, while multiple elements heat source body 508. In some embodiments, multiple heating elements heat source body 508. In some embodiments, one or multiple heating elements heat effusion nozzle 502. In some embodiments, a heating element may be either spiral-wound around the perimeter of source 500 (source body 508), or serpentine with the straight runs of the heating element oriented vertically. Alternatively, a number of single straight heating elements, oriented vertically, may be disposed around source body 508. In some embodiments, the heating element material is graphite. In some embodiments, the heating element material is electrically insulated from source body 508 with a high-temperature electrical insulator such as boron nitride.

Effusion nozzle 502 is situated on one face of source 500. Effusion plume 509 of vapor 514 exits effusion nozzle 502, and is deposited on a substrate.

During operation, some or all of source 500 is maintained at a temperature above the saturation point of vaporized evaporant 501 within source 500 to prevent condensation. An insulating layer typically surrounds substantially the entire source with the exception of effusion nozzle 502 and electrical feed-throughs for the heating elements.

Evaporant 501 may be any element, or compound thereof, that has high vacuum deposition properties in forming a photovoltaic absorber layer. In some embodiments, the element, or compound thereof, comprises silver, copper, indium, gallium and selenium. In use, substrate translation direction during use of source 500 is normal to the plane of the cross-section of source 500 shown in FIG. 12.

In some embodiments, in order to minimize the surface-area-to-volume ratio of source 500, source 500 is cylindrical in geometry; i.e., circular in cross-section when viewed from the bottom. These design considerations do not limit source 500 design to cylindrical designs. Other considerations such as the method of heating may also factor into the choice of source 500 geometry, such as a square or rectangular perimeter instead of a circular perimeter. Furthermore, source 500 is not limited to low-aspect-ratio cross sections. High-aspect-ratio cross sections, with large perimeter-to-area ratios, may also be used.

In an upwards-evaporation source configuration, debris comprising unutilized evaporant 501 materials condenses on the stationary internals of source 500, and therefore cannot fall onto the substrate surface or into effusion nozzle 502.

### Upwards-Evaporating Multiple-Nozzle Centrifugal Sources

FIG. 13 shows a cross-sectional side view of one possible configuration of centrifugal source 600. Viewed from the bottom, the cross-section of source 600 may be circular, square, or rectangular. In some embodiments, source 600 may comprise a threaded lid and body (not shown) for ease of changing evaporant 601.

The device includes a volume of evaporant 601 contained in crucible 604, which also contains vapor space 605 above evaporant 601. Vapors 614 from vapor space 605 enter centrifugal separators 610 through holes 612 in ceiling plates 617 and exit through holes 613 in floor plates 615 into effusion head spaces enclosed by effusion nozzles 602 and exit effusion nozzles 602 as vapor plumes 609. One function of holes 612 (a restriction orifice), and thereby centrifugal separators 610, is to cause evaporant 601 vapor pressure in the effusion head spaces to be less than the thermodynamic saturation pressure of evaporant 601, thereby inhibiting evaporant 601 condensation within the effusion head spaces.

A heating element (typically unitary) heats some or all of source 600. There may be a single heating element, or two or more heating elements. In some embodiments, one heating element primarily heats source body 608, while multiple heating elements heat crucible 604 containing evaporant 601. In some embodiments, one heating element primarily heats crucible 604 and evaporant 601, while multiple elements heat source body 608. In some embodiments, multiple heating elements heat source body 608. In some embodiments, one or multiple heating elements heat effusion nozzles 602. In some embodiments, a heating element may be either spiral-wound around the perimeter of source 600 (source body 608), or serpentine with the straight runs of the heating element oriented vertically. Alternatively, a number of single straight heating elements, oriented vertically, may be disposed around source body 608. In some embodiments, the heating element material is graphite. In some embodiments, the heating element material is electrically insulated from source body 608 with a high-temperature electrical insulator such as boron nitride.

Effusion nozzles 602 are situated on one face of source 600. Effusion plumes 609 of vapors 614 exit effusion nozzles 602, and are deposited on a substrate.

During operation, some or all of source 600 is maintained at a temperature above the saturation point of vaporized evaporant 601 within source 600 to prevent condensation. An insulating layer typically surrounds substantially the entire source with the exception of effusion nozzles 602 and electrical feed-throughs for the heating elements.

Evaporant 601 may be any element, or compound thereof, that has high vacuum deposition properties in forming a photovoltaic absorber layer. In some embodiments, the element, or compound thereof, comprises silver, copper, indium, gallium and selenium. In use, substrate translation direction during use of source 600 is normal to the plane of the cross-section of source 600 shown in FIG. 13.

In some embodiments, in order to minimize the surface-area-to-volume ratio of source 600, source 600 is cylindrical in geometry; i.e., circular in cross-section when viewed from the bottom. These design considerations do not limit source 600 design to cylindrical designs. Other considerations such as the method of heating may also factor into the choice of source 600 geometry, such as a square or rectangular perimeter instead of a circular perimeter. Furthermore, source 600 is not limited to low-aspect-ratio cross sections. High-aspect-ratio cross sections, with large perimeter-to-area ratios, may also be used.

In an upwards-evaporation source configuration, debris comprising unutilized evaporant 601 materials condenses on the stationary internals of source 600, and therefore cannot fall onto the substrate surface or into effusion nozzles 602.

### Sideways-Evaporating Single-Nozzle Centrifugal Sources

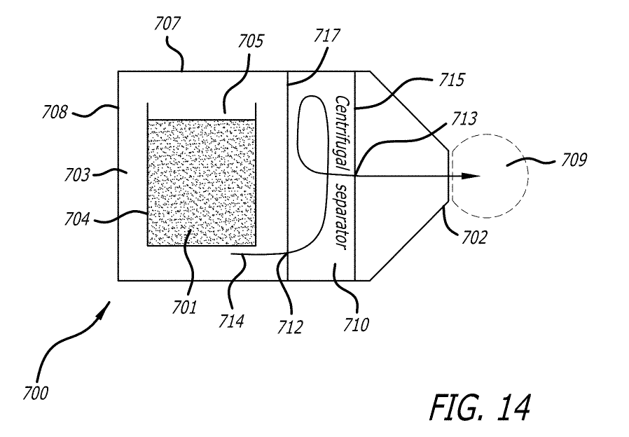

FIG. 14 shows a cross-sectional side view of one possible configuration of centrifugal source 700. Viewed from a side normal to that shown in FIG. 14, the cross-section of source 700 may be circular, square, or rectangular. In some embodiments, source 700 may comprise a threaded lid and body (not shown) for ease of changing evaporant 701.

The device includes a volume of evaporant 701 contained in crucible 704, which also contains vapor space 705 above evaporant 701. Vapor 714 from vapor space 705 enters expansion chamber 703, then enters centrifugal separator 710 through hole 712 in side plate 717 and exits through hole 713 in side plate 715 into an effusion head space enclosed by effusion nozzle 702 and exits effusion nozzle 702 as vapor plume 709. One function of hole 712 (a restriction orifice), and thereby centrifugal separator 710, is to cause evaporant 701 vapor pressure in the effusion head space to be less than the thermodynamic saturation pressure of evaporant 701, thereby inhibiting evaporant 701 condensation within the effusion head space.

A heating element (typically unitary) heats some or all of source 700. There may be a single heating element, or two or more heating elements. In some embodiments, one heating element primarily heats source body 708, or lid 707, while multiple heating elements heat crucible 704 containing evaporant 701. In some embodiments, one heating element primarily heats crucible 704 and evaporant 701, while multiple elements heat source body 708. In some embodiments, one heating element primarily heats lid 707, one heating element primarily heats crucible 704 and evaporant 701, and multiple elements heat source body 708. In some embodiments, multiple heating elements heat source body 708. In some embodiments, one or multiple heating elements heat effusion nozzle 702. In some embodiments, a heating element may be either spiral-wound around the perimeter of source 700 (source body 708), or serpentine with the straight runs of the heating element oriented horizontally. Alternatively, a number of single straight heating elements, oriented horizontally, may be disposed around source body 708. In some embodiments, the heating element material is graphite. In some embodiments, the heating element material is electrically insulated from source body 708 with a high-temperature electrical insulator such as boron nitride.

Effusion nozzle 702 is situated on one face of source 700. Effusion plume 709 of vapor 714 exits effusion nozzle 702, and is deposited on a substrate.

During operation, some or all of source 700 is maintained at a temperature above the saturation point of vaporized evaporant 701 within source 700 to prevent condensation. An insulating layer typically surrounds substantially the entire source with the exception of effusion nozzle 702 and electrical feed-throughs for the heating elements.

Evaporant 701 may be any element, or compound thereof, that has high vacuum deposition properties in forming a photovoltaic absorber layer. In some embodiments, the element, or compound thereof, comprises silver, copper, indium, gallium and selenium. In use, substrate translation direction during use of source 700 is normal to the plane of the cross-section of source 700 shown in FIG. 14.

In some embodiments, in order to minimize the surface-area-to-volume ratio of source 700, source 700 is cylindrical in geometry; i.e., circular in cross-section when viewed from the side. These design considerations do not limit source 700 design to cylindrical designs. Other considerations such as the method of heating may also factor into the choice of source 700 geometry, such as a square or rectangular perimeter instead of a circular perimeter. Furthermore, source 700 is not limited to low-aspect-ratio cross sections. High-aspect-ratio cross sections, with large perimeter-to-area ratios, may also be used.

### Sideways-Evaporating Multiple-Nozzle Centrifugal Sources

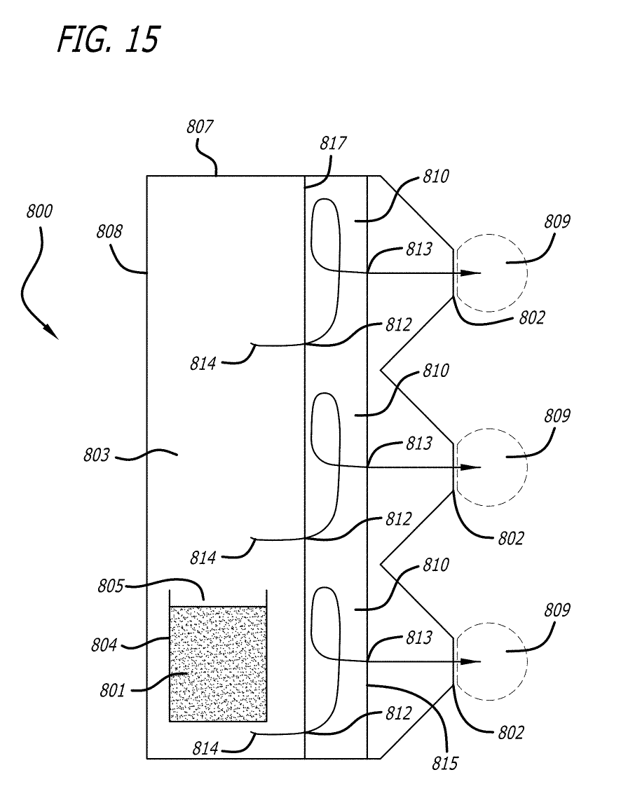

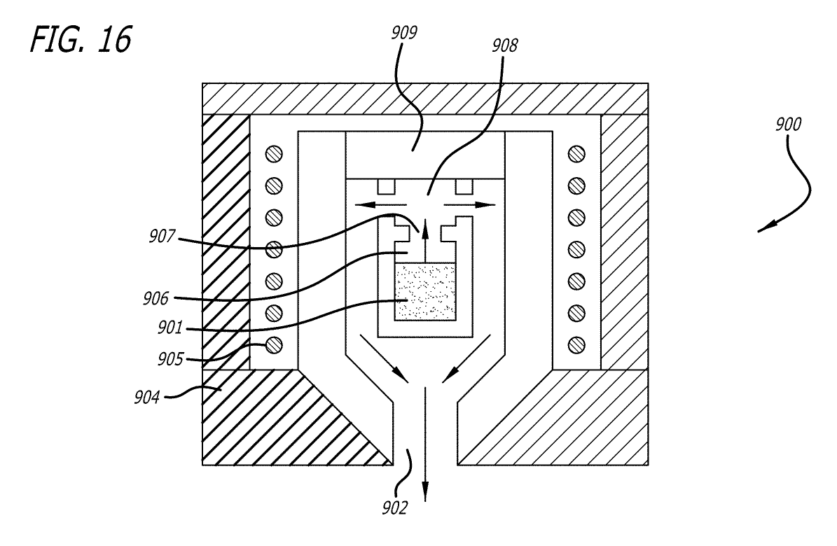

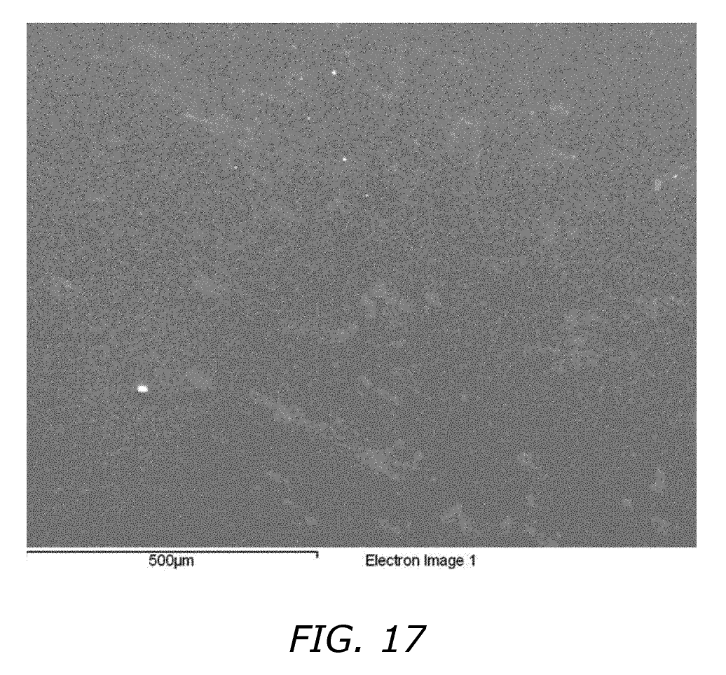

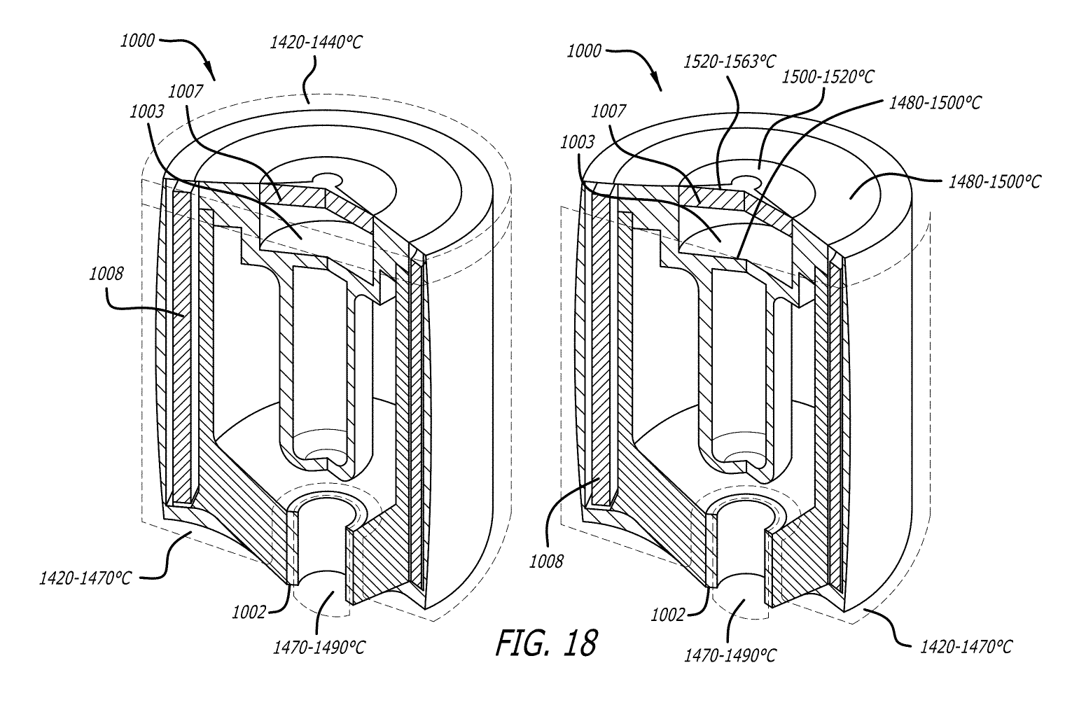

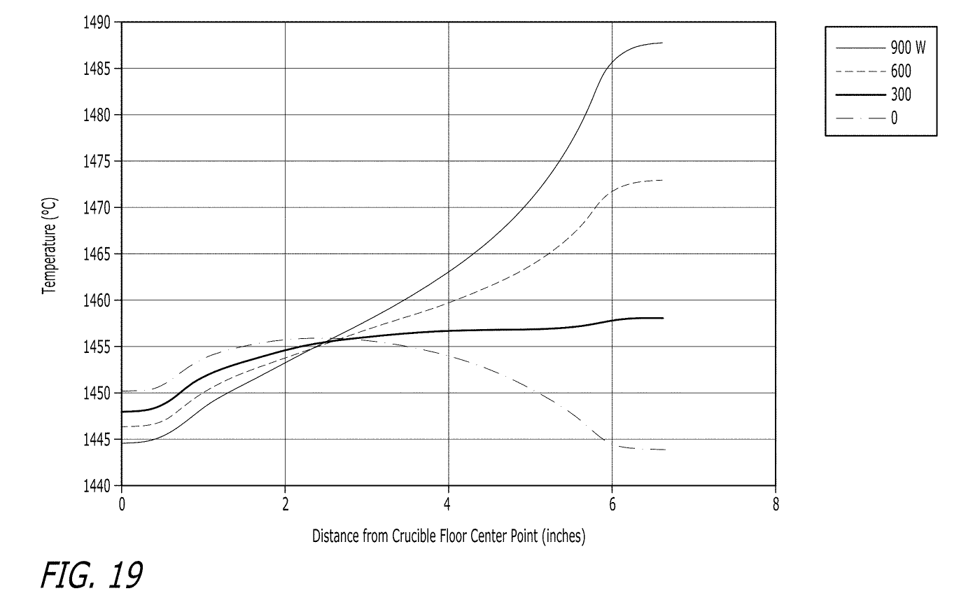

FIG. 15 shows a cross-sectional side view of one possible configuration of centrifugal source 800. Viewed from a side normal to that shown in FIG. 15, the cross-section of source 800 may be circular, square, or rectangular. In some embodiments, source 800 may comprise a threaded lid and body (not shown) for ease of changing evaporant 801.

The device includes a volume of evaporant 801 contained in crucible 804, which also contains vapor space 805 above evaporant 801. Vapors 814 from vapor space 805 enter expansion chamber 803, then enter centrifugal separators 810 through holes 812 in side plate 817 and exit through holes 813 in side plate 815 into an effusion head space enclosed by effusion nozzles 802 and exits effusion nozzles 802 as vapor plumes 809. One function of holes 812 (a restriction orifice), and thereby centrifugal separators 810, is to cause evaporant 801 vapor pressure in the effusion head space to be less than the thermodynamic saturation pressure of evaporant 801, thereby inhibiting evaporant 801 condensation within the effusion head space.

A heating element (typically unitary) heats some or all of source 800. There may be a single heating element, or two or more heating elements. In some embodiments, one heating element primarily heats source body 808, or lid 807, while multiple heating elements heat crucible 804 containing evaporant 801. In some embodiments, one heating element primarily heats crucible 804 and evaporant 801, while multiple elements heat source body 808. In some embodiments, one heating element primarily heats lid 807, one heating element primarily heats crucible 804 and evaporant 801, and multiple elements heat source body 808. In some embodiments, multiple heating elements heat source body 808. In some embodiments, one or multiple heating elements independently heat effusion nozzles 802. In some embodiments, a heating element may be either spiral-wound around the perimeter of source 800 (source body 808), or serpentine with the straight runs of the heating element oriented horizontally. Alternatively, a number of single straight heating elements, oriented horizontally, may be disposed around source body 808. In some embodiments, the heating element material is graphite. In some embodiments, the heating element material is electrically insulated from source body 808 with a high-temperature electrical insulator such as boron nitride.

Effusion nozzles 802 are situated on one face of source 800. Effusion plumes 809 of vapors 814 exit effusion nozzles 802, and are deposited on a substrate.

During operation, some or all of source 800 is maintained at a temperature above the saturation point of vaporized evaporant 801 within source 800 to prevent condensation. An insulating layer typically surrounds substantially the entire source with the exception of effusion nozzle 802 and electrical feed-throughs for the heating elements.

Evaporant 801 may be any element, or compound thereof, that has high vacuum deposition properties in forming a photovoltaic absorber layer. In some embodiments, the element, or compound thereof, comprises silver, copper, indium, gallium and selenium. In use, substrate translation direction during use of source 800 is normal to the plane of the cross-section of source 800 shown in FIG. 15.

In some embodiments, in order to minimize the surface-area-to-volume ratio of source 800, source 800 is cylindrical in geometry; i.e., circular in cross-section when viewed from the side. These design considerations do not limit source 800 design to cylindrical designs. Other considerations such as the method of heating may also factor into the choice of source 800 geometry, such as a square or rectangular perimeter instead of a circular perimeter. Furthermore, source 800 is not limited to low-aspect-ratio cross sections. High-aspect-ratio cross sections, with large perimeter-to-area ratios, may also be used.

### Methods of Construction

The evaporation sources provided herein are typically constructed from graphite or boron nitride, or both, although other materials may be used. Materials of construction should be impervious to and non-reactive with the evaporant material at the temperatures of use, and should remain solid and structurally strong at such temperatures. Temperatures are typically in a range from 1000 to 1600° C.; however, the use of high vapor pressure evaporants such as selenium, which would be expected to evaporate at temperatures between 300-600° C., is not precluded.

To avoid vapor leakage through joints between disparate elements from which the source is constructed, all joints typically will be threaded, with flat mating surfaces to provide a good seal. Optionally, joints may be fabricated with either knife edge or flush mating surfaces and utilize a high temperature gasket material, for example a graphite foil sold under the trade name GRAFOIL® by GrafTech International of Parma, Ohio.

In the case of the sideways-evaporating source, a threaded joint may be utilized to join the manifold and the crucible in a semi-permanent fashion. Additionally, it may be desirable to incorporate a threaded plug at the top of the manifold so that the evaporant may be dropped into the source for replenishing without substantially disassembling the source.

In the case of the single-nozzle downwards-evaporating source, the crucible can drop down into the top of the manifold and screw into place so that it is fixed in a semi-permanent fashion. Additionally, a threaded plug can be incorporated into the top surface of the crucible for adding evaporant to the source.

In the case of the multiple-nozzle downwards-evaporating source, fabrication requires the drilling of multiple internal holes in a solid billet of material. The crucible and expansion chamber may be fabricated by drilling through the entirety of the length of the billet. The ends of these chambers may then be closed off by threading and installing permanent plugs. Likewise, forming the plurality of pathways between the crucible and the expansion chamber requires first drilling through an external wall of the source (either the evaporant or expansion sides) to access the surface of the internal separating wall, continuing on through the internal separating wall, removing the drill, and then threading and plugging the resultant holes in the external wall of the source in a permanent fashion. In some embodiments, a removable threaded plug or plugs can be incorporated in the top surface, or side surface, above the crucible for replenishing the evaporant.

The heating elements may be a refractory metal, preferably tantalum, or less desirably tungsten, or graphite. Considerations such as the form (spiral wound, serpentine, etc.) and difficulty of fabrication assist in determining whether a refractory metal or graphite are preferably used.

The insulation may be either a thick rigid sheet of a low-density ceramic material, an example being alumina-based foam insulation sold by Zircar ceramics. Alternately, insulation may comprise a plurality of radiation shields. Radiation shields may comprise a metal foil, graphite foil, or thin ceramic sheet.

Although the evaporation sources are illustrated and described herein with reference to specific embodiments, they are not intended to be limited to the details shown. Rather, various modifications may be made in the details within the scope and range of equivalents of the claims without departing from the evaporation sources described herein.

The preceding disclosures are illustrative embodiments. It should be appreciated by those of skill in the art that the devices, techniques and methods disclosed herein elucidate representative embodiments that function well in the practice of the present disclosure. However, those of skill in the art should, in light of the present disclosure, appreciate that many changes can be made in the specific embodiments that are disclosed and still obtain a like or similar result without departing from the spirit and scope of the invention.

Unless otherwise indicated, all numbers expressing quantities of ingredients and properties used in the specification and claims are to be understood as being modified in all instances by the term “about.” Accordingly, unless indicated to the contrary, the numerical parameters set forth in the specification and claims are approximations that may vary depending upon the desired properties sought to be obtained by the present invention. At the very least, and not as an attempt to limit the application of the doctrine of equivalents to the scope of the claims, each numerical parameter should at least be construed in light of the number of reported significant digits and by applying ordinary rounding techniques. Notwithstanding that the numerical ranges and parameters setting forth the broad scope of the invention are approximations, the numerical values set forth are reported as precisely as possible. Any numerical value, however, inherently contains certain errors necessarily resulting from the standard deviation found in their respective testing measurements.

The terms “a” and “an” and “the” and similar referents used in the context of describing the invention (especially in the context of the following claims) are to be construed to cover both the singular and the plural, unless otherwise indicated herein or clearly contradicted by context. Recitation of ranges of values herein is merely intended to serve as a shorthand method of referring individually to each separate value falling within the range. Unless otherwise indicated herein, each individual value is incorporated into the specification as if it were individually recited herein. All methods described herein can be performed in any suitable order unless otherwise indicated herein or otherwise clearly contradicted by context. The use of any and all examples, or exemplary language (e.g. “such as”) provided herein is intended merely to better illuminate the invention and does not pose a limitation on the scope of the invention otherwise claimed. No language in the specification should be construed as indicating any non-claimed element essential to the practice of the invention.

The use of the term “or” in the claims is used to mean “and/or” unless explicitly indicated to refer to alternatives only or the alternatives are mutually exclusive, although the disclosure supports a definition that refers to only alternatives and “and/or.”

Groupings of alternative elements or embodiments of the invention disclosed herein are not to be construed as limitations. Each group member may be referred to and claimed individually or in any combination with other members of the group or other elements found herein. It is anticipated that one or more members of a group may be included in, or deleted from, a group for reasons of convenience and/or patentability. When any such inclusion or deletion occurs, the specification is herein deemed to contain the group as modified thus fulfilling the written description of all Markush groups used in the appended claims.

Preferred embodiments of this invention are described herein, including the best mode known to the inventors for carrying out the invention. Of course, variations on those preferred embodiments will become apparent to those of ordinary skill in the art upon reading the foregoing description. The inventor expects those of ordinary skill in the art to employ such variations as appropriate, and the inventors intend for the invention to be practiced otherwise than specifically described herein. Accordingly, this disclosure includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context.

Embodiments of the invention so claimed are inherently or expressly described and enabled herein.

Further, it is to be understood that the embodiments of the invention disclosed herein are illustrative of the principles of the present invention. Other modifications that may be employed are within the scope of the invention. Thus, by way of example, but not of limitation, alternative configurations of the present invention may be utilized in accordance with the teachings herein. Accordingly, the present invention is not limited to that precisely as shown and described.

What is claimed is:

1. A centrifugal evaporation source comprising:
a manifold body;
a crucible configured to contain a volume of evaporant and including a circular cross-section, a bottom, a top rim, and a side wall extension that extends above the top rim to a ceiling of the manifold body to form an annulus with inside walls of the manifold body and to form at least three restriction orifices;
an expansion chamber that is flowably connected to vapor space above the evaporant via the at least three restriction orifices; and
a centrifugal separator chamber that is flowably connected above the evaporant and below the expansion chamber, and circumnavigates the interior of the crucible, wherein the centrifugal separator chamber comprises a first and a second end, the first end of the centrifugal separator chamber is flowably connected to the expansion chamber, and the second end of the centrifugal separator chamber is flowably connected to one or more effusion nozzles.

2. The evaporation source of claim 1, wherein at least one wall of the centrifugal separator chamber comprises a heating element capable of heating the at least one wall of the centrifugal separator chamber to a temperature of between 300° C. and 1,600° C.

3. The evaporation source of claim 1, wherein the one or more effusion nozzles comprise a heating element capable of heating the one or more effusion nozzles independently to a temperature of between 300° C. and 1,600° C.

4. The evaporation source of claim 1, wherein the manifold body comprises a heating element capable of heating the manifold body to a temperature of between 300° C. and 1,600° C.

5. The evaporation source of claim 1, wherein the ceiling of the manifold body comprises a heating element capable of heating the ceiling of the manifold body to a temperature of between 300° C. and 1,600° C.

6. The evaporation source of claim 1, wherein the centrifugal separator chamber is an N-helical centrifugal separator chamber, wherein N is mono, di, tri, quadra, penta, hexa, hepta, octa, nona, or deca, and each helix independently has a first end flowably connected to the expansion chamber and a second end flowably connected to the one or more effusion nozzles.

7. The evaporation source of claim 1, wherein the centrifugal separator chamber is a mono-helical centrifugal separator chamber.

8. The evaporation source of claim 1, wherein the one or more effusion nozzles are oriented to direct a vapor flow out of the thermal evaporation source vertically downward, in one or more horizontal directions, or in one or more directions intermediate between horizontal and vertically downward.

9. The evaporation source of claim 1, wherein the crucible is a crucible formed of boron nitride.

10. The evaporation source of claim 1, wherein the evaporation source includes an effusion nozzle configured to produce a vertically downward vapor flow.

11. The evaporation source of claim 1, wherein the at least three restriction orifices comprises eight orifices evenly spaced around a circumference of the crucible.

12. The evaporation source of claim 1, further comprising a lid attached to the crucible, wherein the lid includes one or more additional restriction orifices.

13. The evaporation source of claim 12, wherein the lid provides an added expansion space.

14. The evaporation source of claim 12, wherein the lid comprises a heating element capable of heating the lid to a temperature of between 300° C. and 1,600° C.

15. The evaporation source of claim 1, wherein the manifold body is formed of graphite.

16. The evaporation source of claim 1, wherein the first end of the centrifugal separator chamber is flowably connected to the evaporant.

17. The evaporation source of claim 1, wherein the second end of the centrifugal separator chamber is flowably connected to the manifold, and the manifold is flowably connected to one or more effusion nozzles.
